(19) United States
(12) Patent Application Publication
(10) Pub. No.: US 2004/0234319 A1
(43) Pub. Date: Nov. 25, 2004

(54) Keyboard rack with palm rest

(76) Inventor: Dennis G. Lee, Aurora, CO (US)

Correspondence Address: KURT LEYENDECKER, 9241 S LARK SPARROW DR., HIGHLANDS RANCH, CO, 80126, US

(21) Appl. No.: 10/839,489

(22) Filed: May 5, 2004

Related U.S. Application Data
(60) Provisional application No. 60/468,781, filed on May 7, 2003.

(51) Int. Cl. H03M 11/00

(52) U.S. Cl. 400/714

(57) ABSTRACT

A foldable keyboard rack is provided which includes a key guard portion adapted to fit over a standard computer keyboard to prevent untimely depression of the keys by a book or other object and a palm rest portion designed to provide the user with an ergonomic hand and wrist position for typing. The key guard folds down over the palm rest portion. The palm rest portion may be used with the keyboard rack in its folded or open position. Hooks or other attachment means attach the palm rest portion to the keyboard.

### REFERENCE TO RELATED APPLICATIONS

This application claims priority to and incorporates herein in its entirety the provisional application No. 60/468,781 filed on May 7, 2003 entitled “KEYBOARD RACK WITH PALM REST”, and having the same inventor as this application.

### FIELD OF THE INVENTION

This invention generally relates computer keyboards. More particularly, this invention pertains to palm rest incorporating a protective keyboard rack.

### BACKGROUND

Keyboard covers have been designed which protect computer keyboards from spills and dust. U.S. Pat. No. 4,060,163 shows a flat plate for placing atop a keyboard with cutouts for the keys to keep the keys from being untimely depressed. The plate is formed of a rigid material and is slightly thicker than the height of the keys. Other patent publications related to keyboard covers include U.S. Pat. No. 5,096,317 which describes a keyboard cover having a separate opening for each key. U.S. Pat. Nos. 5,383,643, 6,010,262, and 889,184 describe keyboard covers and copy holders which do not have openings for striking the keys. U.S. Pat. No. 4,449,763 describes a keyboard cover which allows the user's hand to be inserted beneath the cover to activate the keys. U.S. Design Patent 370,220 depicts a keyboard holder which appears to hold the keyboard at a downward slant away from the user. Patent Cooperation Treaty Publication No. WO 00/46121 describes a decorative keyboard overlay with openings for operating the keys.

Palm rests for use with, or as integral parts of, computer keyboards have also been designed. U.S. Pat. No. 6,430,037 discloses a foldable keyboard cover which in its folded position forms a palm rest for the user, and in its unfolded position, covers the keyboard. U.S. Pat. No. 6,493,218 discloses a computer having a keyboard with a detachable palm rest. U.S. Pat. No. 6,262,716 discloses an auxiliary keypad with a cover that can serve as a palm rest. U.S. Pat. No. 6,040,977 discloses a portable computer having a lid and a palm rest including a numeric keyboard. U.S. Pat. No. 5,724,224 discloses a portable computer having an integrated palm rest and battery pack. U.S. Pat. No. 5,704,698 discloses a keyboard holder (a keyboard slide) having a detachable palm rest. U.S. Pat. No. 5,667,320 discloses a keyboard holder with a detachable palm rest. U.S. Pat. No. 5,596,482 discloses a pivotally attached palm rest and handle for a portable computer. U.S. Pat. No. 5,490,647 discloses a palm rest with an adjustable height. U.S. Pat. No. 5,433,407 discloses a palm rest for use with a computer mouse.

There is a need in the art for an integrated keyboard rack and palm rest which can be quickly and easily positioned for use with a computer keyboard, which prevents untimely depression of the keys and at the same times provides an ergonomic hand position for the user.

### SUMMARY OF THE INVENTION

A folding keyboard rack is provided for use with a computer keyboard having a plurality of keys, comprising a key guard having a height slightly higher than the height of the keys rotatably attached to a palm rest. The key guard prevents a book or other object which may be placed on the key guard, or which may inadvertently slide or drop onto the keyboard from depressing the keys. When limited desk space is available, unused keys such as the optional keys at the right side of the keyboard including a number key bank, usually positioned to the far right of the keyboard, and a navigational key bank containing “home,” “page up,” and other navigational keys, to the left of the number key bank, may be covered with a book, a page to be copied, or other reference material resting on the key guard.

Legs, preferably adjustable legs, are attached to the front of the palm rest portion of the keyboard rack so that the front of the palm rest is or can be elevated to a height such that a user's wrist is positioned at a height greater than or equal to the height of said keys. This is an ergonomically desirable position for typing to prevent fatigue and carpal tunnel syndrome. The legs may be of any design known to the art, including folding legs, legs comprised of an inner and outer cylinder as depicted herein, threaded legs fitting within a grooved sleeve, and the like.

The key guard is preferably made up of bars, e.g., a top bar, two side bars, and a bottom bar, however, it may be also made up of a surface with cutout portions for the keys, of a mesh with cutout portions for the keys, of a support on which a series of posts or pegs are spaced which are higher than the height of the keys, or any other structure providing a surface capable of accommodating a book or paper and keeping it from depressing the keys. Since keyboards vary in their layout, the key guard may be configured in a number of different ways to take advantage of spaces between the keys where the key guard can be supported. For example, typical keyboards have vertical spaces between the number key bank, the navigational key bank, and the main keyboard bank, and they have a horizontal space between the function keys and the number keys above the alphabetical keys. A key guard of this invention can have portions which rest in any of these spaces. In one embodiment, in which the key guard is made up of bars, it may have one, two or more vertical bars spaced between banks of keys in addition to the side bars. It also may have one or more horizontal bars in addition to the top and bottom bars. The bottom bar may be discontinuous, i.e. have a gap in it positioned in use beneath the space bar of the keyboard, for accommodating a user's thumbs. In an embodiment of this invention, the bottom bar is rotatably attached to the palm rest via two hinges, and the gap in the bottom bar extends substantially from one hinge to the other. As will be appreciated by those skilled in the art, any means for rotatably attaching the key guard to the palm rest so that it folds down over the palm rest may be used, such as rings, pieces of flexible connecting material, or other means known to the art.

In one embodiment of this invention, the key guard is omitted and the invention comprises a palm rest rotatably attached to the keyboard. When the adjustable legs at the front of the palm rest are adjusted, the back of the palm rest can rotate to accommodate the adjustment.

This invention includes a folding keyboard rack as described above in combination with a keyboard. The keyboard rack may be adapted to fit many different keyboard configurations. For example, many keyboards have a curved bottom, or a curved space bar, or both, or may have alphabetical and numeric keys divided into two portions and set at a V-angle to each other. The keyboard rack of this invention is shaped to accommodate the keyboard with which it is designed to be used. In an embodiment for use with a keyboard having a straight bottom and in which the bottom of the keys are aligned horizontally, the bottom bar of the key guard is straight (although as discussed above, it preferably is discontinuous with a gap below the space bar). In one embodiment having a curved space bar, the bottom bar of the key guard is tapered or otherwise shaped to accommodate the curvature of the space bar. Similarly, when the entire bottom of the keyboard is curved, the bottom bar is shaped to fit the curvature.

In one embodiment of this invention, the palm rest portion of the keyboard rack is equipped with hooks or other means of attachment for attaching it to the keyboard. The hooks preferably have an elastic portion, e.g. a piece of elastomer, or a spring, or other extendible element known to the art, so that the connecting hook stays put without moving against or toward the keys when the front part of the palm rest is elevated to adjust its height and so that the keyboard rack may be easily removed and attached to the keyboard.

The palm rest portion of the keyboard rack of this invention is designed so that the user's palm, e.g., the proximal portion of the user's palm, or wrist, can rest on the palm rest while the user is typing. The palm rest portion may have more than one section for resting the user's palm or wrist. For example, in embodiments of this invention in which the key guard comprises horizontal and/or vertical bars in addition to the top, bottom and side bars, the palm rest portion will comprise grooves into which these bars fit when the key guard is folded over onto the palm rest, thus dividing the palm rest into a plurality of palm rests. The palm rest(s) may be cushioned, may be formed of cushions attached to a base, or may simply be raised portions of the palm rest portion of the device. Preferably, when the key guard comprises top and side bars, the raised palm rests are indented from the edges of the palm rest portion to leave a ledge on which the top and side bars of the key guard fit when the device is folded. The palm rest portion of the device can still be attached to the keyboard and used when the device is folded.

The device may be made of any suitable material or materials, including plastic, metal, wood, and the like. Preferably the components are made of molded plastic. Preferably the key guard is formed of molded plastic as an integral unit. Also preferably, the palm rest portion is molded from plastic as an integral piece. The legs, or a portion thereof, may be molded as part of the palm rest portion. Preferably the outer cylinders of the adjustable legs depicted herein are molded integrally with the palm rest portion. Alternatively, the legs may be attached to the palm rest portion by any means known to the art.

The key guard element and palm rest element as described above are assembled such that the key guard can be folded over onto the palm rest element, and preferably the palm rest element is configured so that the key guard nests therein. The key guard is rotatably attached to the palm rest element by means known to the art such as hinges, hooks or the like. The legs may then be attached, or if a portion of the legs is already part of the palm rest element, the legs may be assembled. In a preferred embodiment, the inner cylinder of the legs is equipped with a peg for adjustment of the legs, and inserted into the outer cylinder which is provided as an integral part of the palm rest element.

### BRIEF DESCRIPTION OF THE DRAWINGS

FIG. 1 is a perspective view of the keyboard rack of this invention in the open position.

FIG. 2 is a top view of the open keyboard rack positioned for use on a computer keyboard with the key guard over the keys and the palm rest in place.

FIG. 3 is a top view of the keyboard rack in folded position with the palm rest in position for use.

FIGS. 4A-C depict the adjustable leg for the keyboard rack shown in FIG. 1. FIG. 4A is a perspective view of the outer cylinder of the adjustable leg. FIG. 4B is a perspective view of the inner cylinder of the adjustable leg. FIG. 4C is a bottom view of the adjustable leg.

FIG. 5A is a perspective top view of a further embodiment of the keyboard rack of this invention in the open position.

FIG. 5B is a perspective top view of the keyboard rack of FIG. 5A in folded position.

FIG. 5C is a perspective bottom view of the keyboard rack of FIG. 5A in folded position.

FIG. 6 is a perspective view of a palm rest of this invention attached to a keyboard.

### DETAILED DESCRIPTION

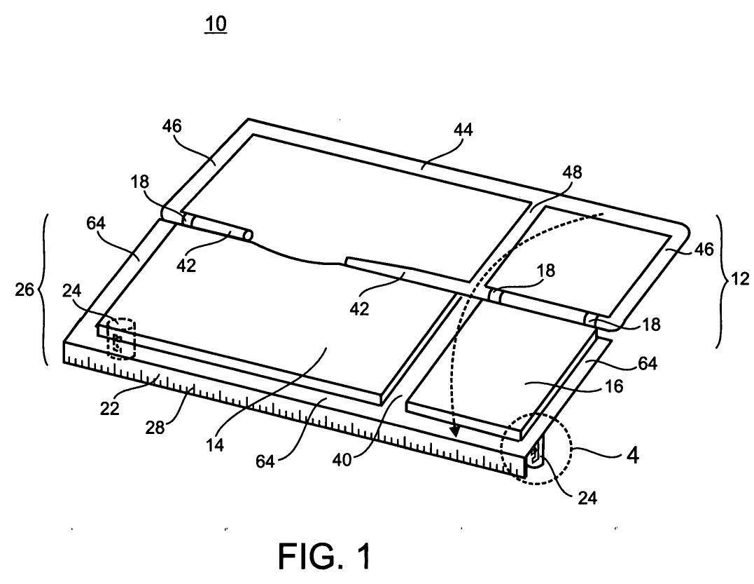

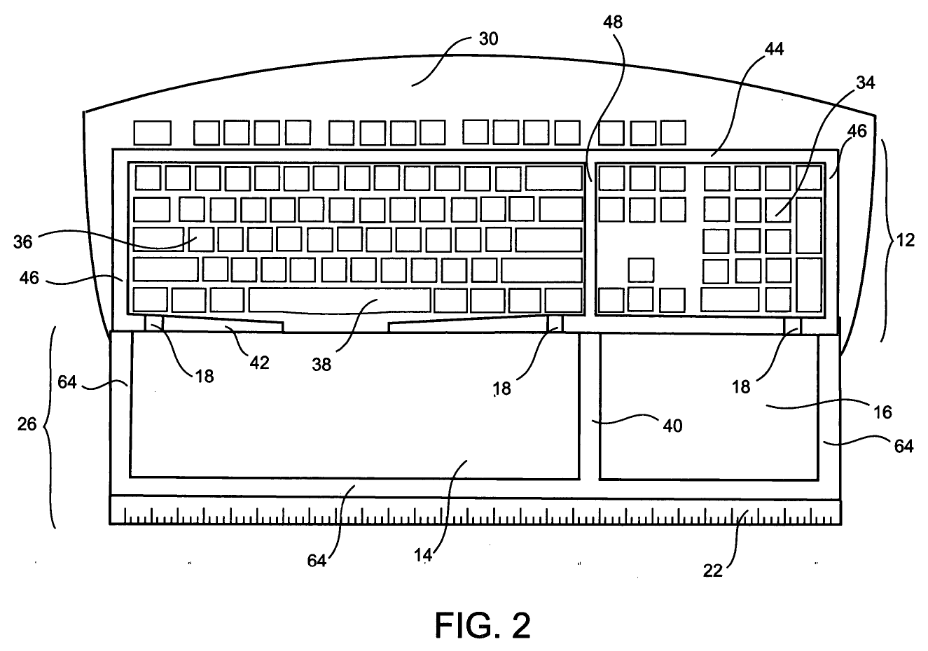

FIG. 1 depicts the keyboard rack with palm rest 10 of this invention. The rack comprises a top key guard portion 12 and a bottom palm rest portion 26. The key guard portion 12 comprises a top key guard bar 44 designed to be positioned between a top row of function keys and a second row of number keys on a standard keyboard as shown in FIG. 2. Alternatively, top key guard bar 44 can be positioned above the top row of function keys. Top key guard portion 12 also comprises two side key guard bars 46, a bottom key guard bar 42, and optionally a middle key guard bar 48. Additional key guard bars may be present, e.g., bars can be designed to fit both horizontally above the top row of function keys and between the function keys and the second row of number keys on a standard keyboard. Vertical bars can also be placed in any suitable vertical space such as a vertical space to the left of a bank of number keys on the right side of the keyboard and a further set of optional keys to the right of the standard alphanumeric keys of the keyboard. Also, as will be appreciated by those skilled in the art, any bar may be discontinuous so long as the discontinuity does not allow key guard portion 12 to warp out of a single plane. The bottom key guard bar 42 is discontinuous so as to accommodate a user's thumbs when the thumbs are positioned to depress the space bar of a standard keyboard. The portions of bottom bar 42 adjacent to the discontinuity in the bar are shown as tapered to accommodate curvature of a keyboard. As will be understood by those skilled in the art, such tapering is unnecessary when the bottom of the keyboard with which the rack is to be used is straight. The key guard portion 12 may be fashioned out of any suitable material such as wood, plastic, metal, rubber or other material providing sufficient rigidity to support the weight of a book, box, or other object which might be placed over it, without allowing the object to depress a key of the keyboard. In one embodiment, the key guard portion 12 is molded from plastic. Further, the bars of key guard portion 12 may be of any cross-section, round, half-round, square, polygonal, or other. The arrow shown in FIG. 1 indicates that the key guard portion 12 may be rotated on hinges 18 to a folded position as shown in FIG. 2.

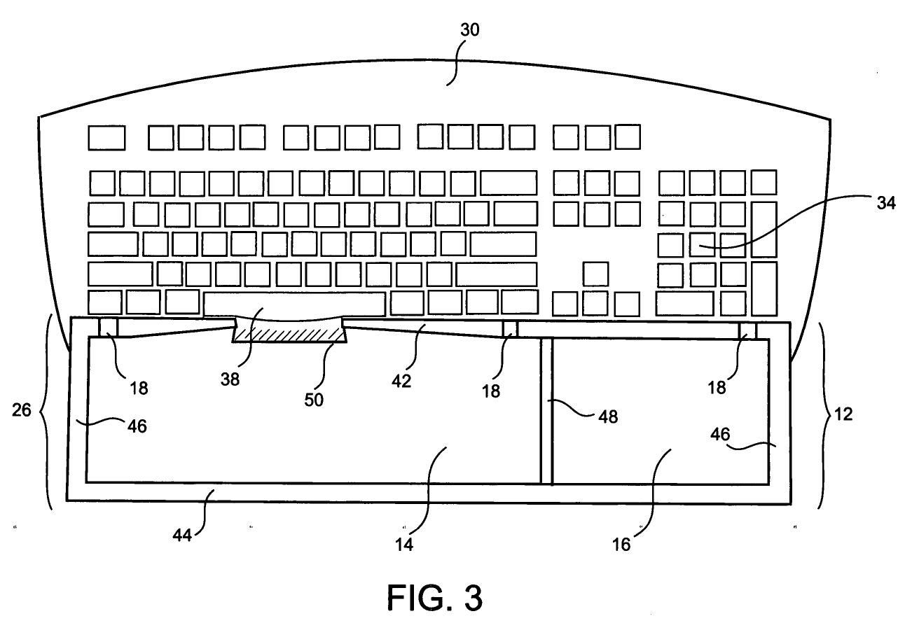

Key guard portion 12 is attached to palm rest portion 26 by means of hinges 18, or other suitable fastening allowing rotation of key guard portion 12. Palm rest portion 26 comprises first palm rest 14 and optional second palm rest 16. Palm rests 14 and 16 are raised and are inset from the side and bottom edges of palm rest portion 26 so as to leave a ledge 64 of a size suitable to accommodate the top and side key guard bars 44 and 46 when the key rack is in its folded position (as shown in FIG. 3). When middle key guard bar 48 is present in the keyboard rack, palm rest portion 26 also comprises key guard channel 40 to accommodate middle key guard bar 48 when the rack is in its folded position. Palm rest portion 26 may be made of any suitably durable material, preferably the same material from which key guard portion 12 is made. Palm rests 14 and 16 may be made of the same material as the remainder of palm rest portion, or may comprise or be made entirely of cushions made of any suitable material or materials, e.g. leather stuffed with fiber fill. The front side 22 of key guard portion 26 is optionally marked with ruler marks 28 so that it can be used as a measuring device. Key guard portion 26 is also equipped with adjustable legs 24 which allow the height of the front of palm rest portion 26 to be adjusted to two or three levels.

FIG. 2 depicts the open keyboard rack positioned over a standard computer keyboard 30 having keys 34 and space bar 38 with key guard 12 placed over the keys and palm rest portion 26 positioned beneath the keyboard so as to accommodate a user's palms. The discontinuity in bottom key guard bar 42 is positioned beneath space bar 38 to accommodate a user's thumbs.

FIG. 3 depicts the keyboard rack in folded position with the key guard portion 12 folded over palm rest portion 26 which remains in position to support the user's palms while typing. Bottom key guard bar 42 rotates on hinges 18 as shown by the arrow in FIG. 1 so that top key guard bar 44 and side key guard bars 46 rest on ledge 64 shown in FIG. 2, and middle key guard bar 48 rests in key guard channel 40 shown in FIG. 2. A thumb ramp 50 slopes downward adjacent the discontinuity in bottom key guard bar 42 to provide a surface for the user's thumbs to rest upon.

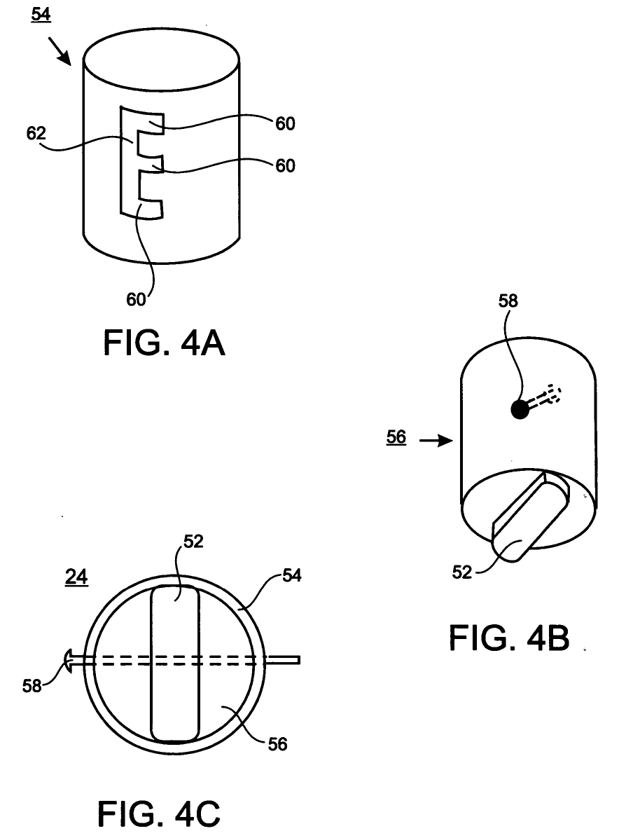

FIGS. 4A-C depict the adjustable leg 24. FIG. 4A is the outer cylinder 54 of the adjustable leg comprising a cut-out portion forming vertical adjustment slot 62 and horizontal locking slots 60. The reverse side of outer cylinder 54 also comprises a cut-out portion identical to that shown. Both cut-out portions are aligned so that peg 58 shown in FIGS. 4B and 4C can engage with both cut-out portions at once. FIG. 4B depicts the inner cylinder 56 of the adjustable leg which is sized and designed to fit within outer cylinder 54 so that peg 58 can engage with slots 60 and 62. FIG. 4C is a bottom view of adjustable leg 24 showing inner cylinder 56 disposed within outer cylinder 54 with peg 58 extending through inner cylinder and emerging through the cut-out portions (not shown) of outer cylinder 54. The adjustable leg 24 is also equipped with an adjustment grip 52 by which the user can turn inner cylinder 56 within outer cylinder 54, causing peg 58 to move in and out of any locking slot 60 and slide along adjustment slot 62, thereby adjusting the height of adjustment leg 24, and consequently adjusting the height of the front portion of palm rest portion 26 of keyboard rack 10.

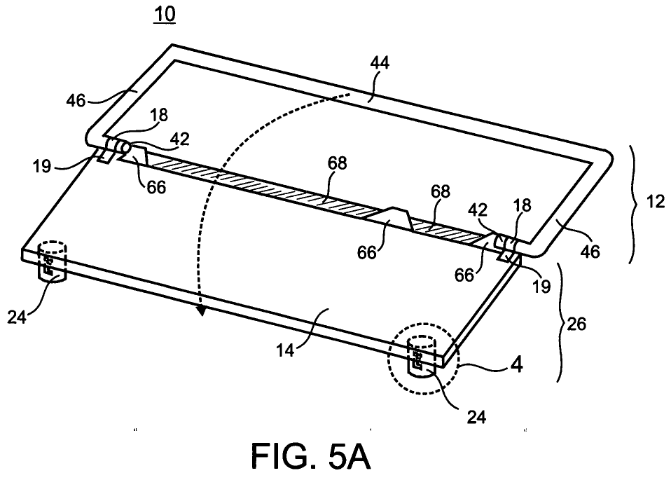

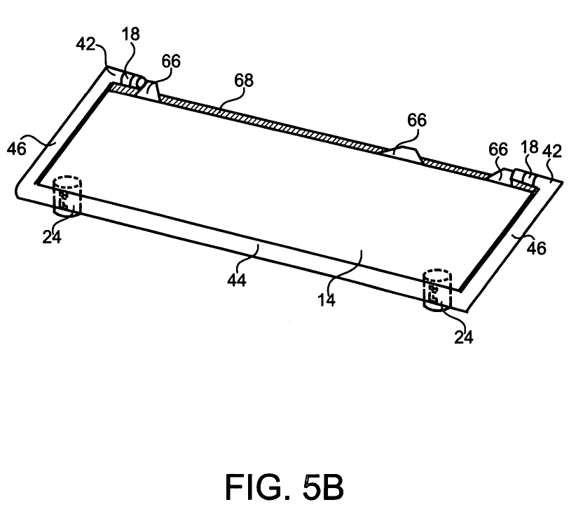

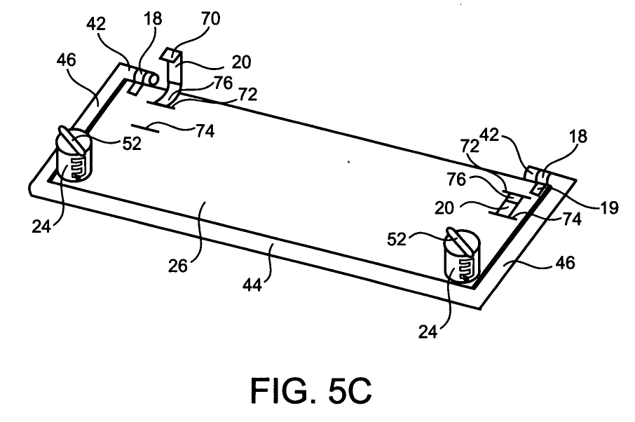

FIGS. 5A-C depict another embodiment of this invention in which the key guard 12 lacks a middle bar and has an extended discontinuity in bottom bar 42. Palm rest portion 26 lacks a ledge around the sides and bottom of palm rest 14, and palm rest 14 is a single piece rather than being split into two palm rest portions as shown in FIG. 1. Top key guard bar 44 and side key guard bars 46 are as described above. Palm rest portion 26 is equipped with raised portions 66 having a top equal in height to the top of top and side bars 44 and 46. Palm rest portion 26 is also preferably equipped with a ramped edge 68 slanting downward in the direction of key guard 12 to accommodate a user's thumbs. Hinges 18 rotatably secure the ends of bottom bar 42 to palm rest portion 26. In the embodiment shown, hinges 18 are equipped with hinge tabs 19 which are secured by means known to the art such as gluing or screwing, to palm rest portion 26. Palm rest portion 26 is also equipped with adjustable legs 24 as described above. The arrow in FIG. 5A indicates that key guard 12 can be rotated around on bottom bar 42 to a folded position as shown in FIG. 5B. FIG. 5C shows the bottom of the folded keyboard rack of FIG. 5B in which hinges 18 and hinge tabs 19 are visible, along with top key guard bar 44 and side key guard bars 56, as well as adjustable legs 24. In addition, hooks 20 are depicted on either side attached to the bottom of palm rest portion 26 by means of hook attachments 72, which may be any structure known to the art, such as a bar embedded in or attached to the bottom of palm rest portion 26, around which the attached end of hook 20 is rotatably fixed. Hook 20 is equipped with a hook portion 70 for insertion into and engagement with hook slot 74 when the keyboard rack 10 is not in use with a keyboard. Hook 20 also preferably comprises an elastic portion 76. The left side of FIG. 5C depicts hook 20 in its open position, while the right side of FIG. 5C depicts hook 20 in its closed or hooked position. In use, when the keyboard rack 10 is positioned for use with a keyboard in either its open or folded position, the hook portion 70 of hook 20 fits into the crack between the frame of the keyboard and the bottom row of keys. The elastic portion 76 of hook 20 allows the rack 10 to be adapted to different keyboard dimensions. When rack 10 is in its folded position and being used with a keyboard only for its palm rest function, elastic portion 76 of hook 20 also allows the palm rest to remain attached even when pressure away from the keyboard is exerted by the user's palms as sometimes happens during normal use.

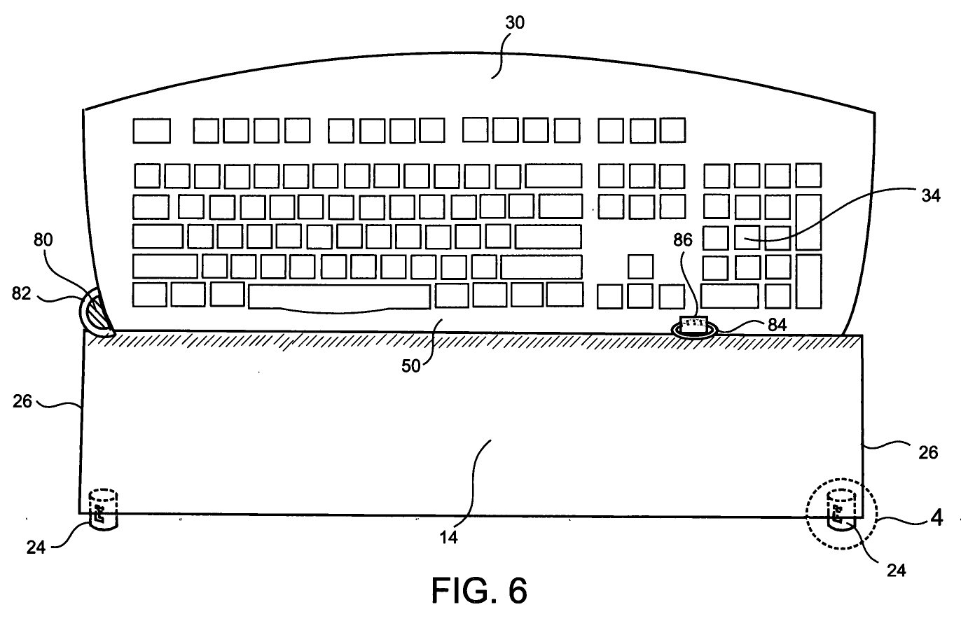

FIG. 6 is a perspective view of an embodiment of this invention in which a palm rest 26 is attached to keyboard 30. The key guard is omitted. The palm rest includes adjustable legs 24 on the front of the palm rest and means for rotatably attaching the palm rest 26 to keyboard 30. Such means include rounded tab 80 which may be molded as part of the keyboard, with corresponding gripping member 82, which may be molded as part of the palm rest, which snaps onto rounded tab 80, shown on the left side of FIG. 6. Such means for rotatably attaching palm rest 26 also include a snap ring 84 which may be molded as part of palm rest 26 which snaps into ring tab 86, which can be molded as part of keyboard 30, shown on the right side of FIG. 6. When adjustable legs 24 are adjusted, the palm rest can rotate on rounded tab 80 or ring tab 86 to accommodate the adjustment.

The keyboard rack of this invention has been described in terms of certain specific features, however any element of the rack may be substituted with an equivalent structural or functional element as known to the art, and devices with such substitutions are considered to be within the scope of the claims appended hereto.

1. A folding keyboard rack for use with a computer keyboard having a plurality of keys, comprising a key guard having a height slightly higher than the height of the keys, the key guard being rotatably attached to a palm rest.

2. The folding keyboard rack of claim 1 having adjustable legs attached to said palm rest.

3. The keyboard rack of claim 2 wherein said adjustable legs allow said palm rest to be elevated to a height such that a user's wrist is positioned at a height greater than the height of said keys.

4. The keyboard rack of claim 2 wherein said adjustable legs allow said palm rest to be elevated to a height such that a user's wrist is positioned at a height equal to the height of said keys.

5. The folding keyboard rack of claim 1 wherein said key guard comprises a top bar, two side bars, and a bottom bar.

6. The folding keyboard rack of claim 5 wherein said bottom bar is discontinuous, having a gap therein positioned in use beneath a space bar of said keyboard, for accommodating a user's thumbs.

7. The folding keyboard rack of claim 6 wherein said bottom bar is rotatably attached to said palm rest via two hinges, and said gap extends substantially from one hinge to the other.

8. The keyboard rack of claim 5 wherein said bottom bar is rotatable attached to said palm rest.

9. The folding keyboard rack of claim 1 in combination with a keyboard.

10. The folding keyboard rack of claim 1 adapted to fit a keyboard having a curved spacebar.

11. The folding keyboard rack of claim 1 adapted to fit a keyboard having a curved bottom.

12. The folding keyboard rack of claim 1 adapted to fit a keyboard having a straight bottom.

13. The keyboard rack of claim 1 wherein said palm rest comprises hooks for hooking said keyboard rack to said keyboard.

14. A folding keyboard rack for use with a computer keyboard comprising a plurality of keys, comprising a key guard having a height slightly higher than the height of the keys rotatably attached to a palm rest portion, wherein said key guard is formed of a single molded piece.

15. The keyboard rack of claim 14 wherein said palm rest portion comprises legs, and said palm rest portion, excluding said legs, is formed of a single molded piece.

16. The keyboard rack of claim 14 wherein said palm rest portion comprises legs, and said palm rest portion including at least a portion of said legs, is formed of a single molded piece.

17. The keyboard rack of claim 14 wherein said portion of said legs is an outer cylinder.

18. The keyboard rack of claim 1 wherein said palm rest comprises a front side marked as a ruler.

19. A method of making a keyboard rack of claim 1 comprising:
providing a key guard element;
providing a palm rest element; and
rotatably attaching said key guard element to said palm rest element.

20. The method of claim 24 further comprising attaching legs to said palm rest element.
